(19) United States
(12) Patent Application Publication
(10) Pub. No.: US 2007/0111380 A1
(43) Pub. Date: May 17, 2007

(54) Fabricating method of printed circuit board having embedded component

(75) Inventors: Suk-Hyeon Cho, Suwon-si (KR); Chang-Sup Ryu, Yongin-si (KR); Han-Seo Cho, Daejeon (KR); Han Kim, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon-si (KR)

(21) Appl. No.: 11/598,141

(22) Filed: Nov. 13, 2006

(30) Foreign Application Priority Data
Nov. 17, 2005 (KR) 10-2005-0110166

(51) Int. Cl. H01L 21/00

(52) U.S. Cl. 438/106

(57) ABSTRACT

A method of fabricating a printed circuit board having embedded components is disclosed. The method of fabricating a printed circuit board having embedded components according to an embodiment of the present invention comprises stacking a first conductive layer and a second conductive layer on a substrate in order, forming a hole in the second conductive layer and filling with dielectric material, stacking a third conductive layer on the second conductive layer and removing portions to form an upper electrode located on the dielectric material and a pad electrically connected with the first conductive layer, and stacking an insulation layer on the third conductive layer and forming a via hole and an outer layer circuit electrically connected with the upper electrode and the pad, so that it is easy to process the dielectric material to have a uniform thickness, and the capacitor and the resistor can be implemented simultaneously.

### CROSS-REFERENCE TO RELATED APPLICATIONS

This application claims the benefit of Korean Patent Application No. 2005-0110166 filed with the Korean Intellectual Property Office on Nov. 17, 2005, the disclosure of which is incorporated herein by reference in its entirety.

### BACKGROUND

1. Technical Field

The present invention relates to a method of fabricating a printed circuit board having embedded electronic components.

2. Description of the Related Art

In accordance with recent trends toward smaller, thinner, and lighter electronic products, there is a demand also for smaller and lighter printed circuit boards (PCB's) used in such products. In the printed circuit board for a conventional package, passive elements such as capacitors and resistors are mounted on the surface of the printed circuit board. However, in electronic products that are everyday becoming smaller and more dense, not only is the surface area of the printed circuit board itself decreased, but also the number of electronic components mounted on the surface is increased. This has led to difficulties in the surface-mounting of electronic components, and thus an embedding process is widely used, which embeds electronic components within the printed circuit board.

The embedding process places electronic components, such as capacitors and resistors, inside the board, which reduces the thickness and size of the board and shortens the lengths of circuits. This decreases the impedance, which reduces noise and allows a stable supply of power.

A conventional method of embedding a capacitor includes coating photosensitive material on the entire surface, stacking on and hot-pressing a copper foil, removing the copper foil by etching, and then selectively removing unnecessary portions by UV-irradiation. Another method includes hot-pressing a copper foil, which already has a coating of insulation material, to attach it onto an inner layer board, which has circuits formed thereon, and then selectively removing the copper foil to use the remaining portions as upper electrodes. Also, in some cases, a method is used of removing the insulation layer as necessary.

However, the methods above entail problems in that the fabricating process is made complicated and it is difficult to obtain uniformity in the thickness of the dielectric material. Also, since the capacitor and the resistor are formed separately, the fabricating process is complicated, and there are many limitations in design due to the difficulty in securing space inside the board.

### SUMMARY

The present invention aims to provide a method of fabricating a printed circuit board having embedded components, with which it is easy to process the dielectric material to have a uniform thickness.

The invention also aims to provide a method of fabricating a printed circuit board having embedded components, with which the capacitor and the resistor can be implemented simultaneously.

Another object of the invention is to provide a method of fabricating a printed circuit board having embedded components, with which the inductor can be implemented using a process for fabricating the capacitor.

One aspect of the present invention provides a method of fabricating a printed circuit board having embedded components, comprising stacking a first conductive layer and a second conductive layer in order on a substrate, forming a hole in the second conductive layer and filling with dielectric material, stacking a third conductive layer on the second conductive layer and removing portions to form an upper electrode located on the dielectric material and a pad electrically connected with the first conductive layer, and stacking an insulation layer on the third conductive layer and forming a via hole and an outer layer circuit electrically connected with the upper electrode and the pad.

Embodiments of the invention may additionally include the following features. For example, the substrate may be a copper clad laminate. The first conductive layer may be made of a nickel alloy, the second conductive layer may be a copper foil and the first conductive layer may have a greater electrical resistance than that of the second conductive layer. The hole may be formed by means of a copper etchant. The dielectric material may be filled in by screenprinting or may be filled in by means of an inkjet printer.

An additional conductive material, such as gold or silver, may be plated on the first conductive layer exposed to the exterior after forming the hole. An additional treatment process for forming surface roughness may be applied on the first conductive layer exposed to the exterior after forming the hole.

The third conductive layer may be formed by copper plating. The first conductive layer may be made of a nickel alloy layer stacked on the substrate and a material high in electrical conductivity stacked on the nickel alloy layer. A heat-releasing layer, which has high heat conductivity and which is electrically nonconductive, may additionally be positioned between the substrate and the first conductive layer. The heat-releasing layer may be formed from a composite material which includes a polymer resin, ceramic, a combination of a polymer resin and ceramic, or metal.

Another aspect of the invention provides a method of fabricating a printed circuit board having embedded components, comprising stacking a first conductive layer and a second conductive layer in order on a substrate, forming a hole in the second conductive layer to expose a portion of the first conductive layer to the exterior, removing the portion of the first conductive layer exposed by the hole to form a portion of a lower inductor part, filling the hole with insulation material, and stacking a third conductive layer on the second conductive layer and removing a portion to form a portion of an upper inductor part connected with the lower inductor part.

Yet another aspect of the invention provides a method of fabricating a printed circuit board having embedded components, comprising stacking a first conductive layer and a second conductive layer on a substrate in order, removing portions of the first conductive layer and the second conductive layer and forming a hole to expose a portion of the substrate to the exterior, removing a portion of the second conductive layer to form a portion of a lower coil of an inductor, filling the hole with -insulation material, and stacking a third conductive layer on the second conductive layer and removing a portion of the third conductive layer to form a portion of an upper coil connected with the lower coil.

Embodiments of the invention may additionally include the following features. For example, the substrate may be a copper clad laminate, and the second conductive layer may be a copper foil. The hole may be formed by means of a copper etchant.

The lower inductor part may be formed by coating photosensitive material on the first conductive layer and the second conductive layer exposed to the exterior by the hole and removing portions of the first conductive layer by means of an etching process. The insulation material may be a nonconductive ferromagnetic material, such as ferrite or cobalt, or may be a ferromagnetic material treated on the surface with insulation material.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view after a first conductive layer and second conductive layer have been stacked on a substrate, in a method of fabricating a printed circuit board having embedded components according to an embodiment of the present invention.

FIG. 2 is a cross-sectional view after a portion of the second conductive layer of FIG. 1 has been removed to form a hole.

FIG. 3 is a cross-sectional view after dielectric material has been filled in the hole illustrated in FIG. 2.

FIG. 4 is a cross-sectional view after the dielectric material has been filled in and a third conductive layer has been stacked on the second conductive layer.

FIG. 5 is a cross-sectional view after an upper electrode and a pad have been formed.

FIG. 6a is a cross-sectional view illustrating the upper electrode and pad.

FIG. 6b is a plan view of the upper electrode and pad of FIG. 6a.

FIG. 7a is a plan view after an upper electrode and a pad have been formed on the dielectric material according to another embodiment of the present invention.

FIG. 7b is a plan view of an upper electrode and a pad according to still another embodiment of the present invention.

FIG. 7c is a plan view of an upper electrode and pads according to yet another embodiment of the present invention.

FIG. 8 is a cross-sectional view after insulation material has been coated on the third conductive layer and holes have been formed.

FIG. 9 is a cross-sectional view after the forming of via holes and plating in FIG. 8 and after an outer layer circuit has been formed.

FIG. 10a is a plan view after a hole has been formed in a second conductive layer to expose a portion of a first conductive layer; in an embodiment of the invention for forming an inductor.

FIG. 10b is a cross-sectional view across line AA′ of FIG. 10a.

FIG. 11a is a plan view after photosensitive material has been coated on the second conductive layer of FIG. 10a.

FIG. 11b is a cross-sectional view across line AA′ of FIG. 11a.

FIG. 12a is a plan view after portions of lower inductor parts have been formed in FIG. 11a and after the photosensitive material has been removed.

FIG. 12b is a cross-sectional view across line AA′ of FIG. 12a.

FIG. 13a is a plan view after insulation material has been filled in the hole of FIG. 12a.

FIG. 13b is a cross-sectional view across line AA′ of FIG. 13a.

FIG. 14a is a plan view after a third conductive layer has been stacked on the second conductive layer of FIG. 13a.

FIG. 14b is a cross-sectional view across line AA′ of FIG. 14a.

FIG. 15a is a plan view after portions of the third conductive layer in FIG. 14a have been removed to form portions of upper inductor parts.

FIG. 15b is a cross-sectional view across line AA′ of FIG. 15a.

FIG. 16 is a plan view illustrating an inductor having the form of a ring.

FIG. 17a is a plan view after portions of a first conductive layer and a second conductive layer have been removed using photosensitive material to form holes, in a method of fabricating a printed circuit board having embedded components according to another embodiment of the present invention.

FIG. 17b is a cross-sectional view across line AA′ of FIG. 17a.

FIG. 18a is a plan view after portions of the photosensitive material and the second conductive layer in FIG. 17a have been removed.

FIG. 18b is a cross-sectional view across line AA′ of FIG. 18a.

### DETAILED DESCRIPTION

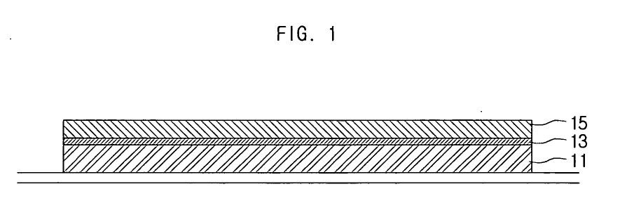

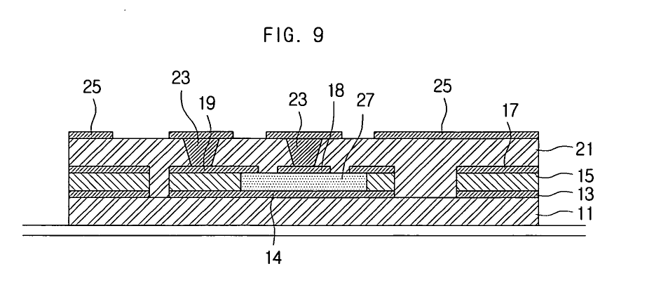

Embodiments of methods of fabricating an embedded capacitor and an embedded inductor according to the present invention will be described below in more detail with reference to the accompanying drawings. In the description with reference to the accompanying drawings, those components are rendered the same reference number that are the same or are in correspondence regardless of the figure number, and redundant explanations are omitted. Below, a method of fabricating a printed circuit board having a capacitor and a resistor according to an embodiment of the invention will be described with reference to FIGS. 1 to 9. Referring to FIG. 1, a first conductive layer 13 and a second conductive layer 15 are stacked in order on a substrate 11. The substrate 11 may be a copper clad laminate (CCL), which has copper foil stacked on one or both sides of an insulation layer, where the insulation layer is manufactured by stacking several sheets of insulation material, such as paper or glass, etc., and resin and then treating with hot-pressing. The first conductive layer 13 may be a nickel alloy layer, which is not removed by copper etchant, and is placed in contact with the second conductive layer 15. The first conductive layer 13 will be made, by subsequent processes, into the lower electrode (14 of FIG. 9) of a capacitor. The second conductive layer 15 may be a copper foil plated on the upper portion of the first conductive layer 13. The second conductive layer 15, as illustrated in FIG. 9, electrically connects the lower electrode 14 and the pad 19. Although it is not shown in the figure, a heat-releasing layer (not shown) which has high heat conductivity and no electrical conductivity may be positioned between the substrate 11 and the first conductive layer 13. The electrically nonconductive material allows the heat released by the capacitors or resistors, etc., to be readily emitted to the exterior. The electrically nonconductive material may be a composite material which includes a polymer resin, ceramic, a combination of a polymer resin and ceramic, or metal.

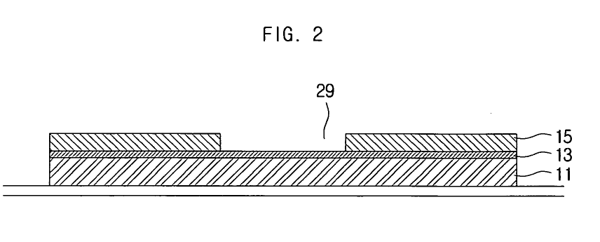

Referring to FIG. 2, a hole 29 is formed in a designated location of the second conductive layer 15 into which dielectric material is filled. As the hole 29 is formed in the thickness of the second conductive layer 15 (generally several to several tens of μm), the thickness of the dielectric material may be made thin. The hole 29 may be formed by removing a portion of the second conductive layer 15 using a copper etchant, with which it is possible to selectively etch only the copper foil. Here, the first conductive layer 13 is not removed by the etchant, because it is made of a nickel alloy layer, etc., which is not removed by copper etchant.

The dielectric material 27 may be common capacitor powder, a material having high electrical capacitance. For example, BaTiO₃ ceramic powder, thermosetting epoxy resin, polyimide, or a composite material thereof may be used, which have dielectric constants between 1,000 and 10,000.

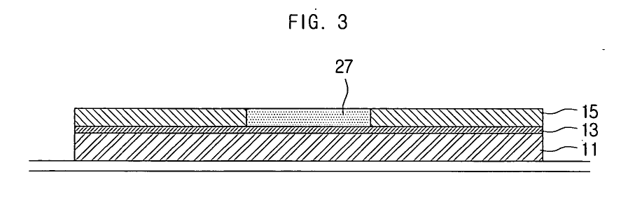

After forming the hole 29 and before filling in the dielectric material 27 as illustrated in FIG. 3, the surface of the first conductive layer 13 exposed to the exterior by the hole 29 may be plated using gold or silver, which have high electrical conductivity. This is to increase the capacity of the capacitor by stacking a conductor high in electrical conductivity on the lower electrode of the capacitor. Also, to increase the adhesive force between the dielectric material 27 and the insides of the hole 29, a surface treatment for forming surface roughness may be applied on the surface of the first conductive layer 13 exposed to the exterior by the hole 29. Examples of surface treatment processes include surface etching, etc.

Referring to FIG. 3, dielectric material 27 is filled inside the hole 29. Methods of filling in the dielectric material 27 include screenprinting using a metal mask (not shown) and printing using an inkjet printer, etc. If the thickness of the dielectric material 27 is not equal to the thickness of the second conductive layer 15, an abrasive machine, etc., may be used to produce a uniform thickness. Thus, as the dielectric material is filled in a hole 29 of a low depth, it is easy to form the dielectric material to have a thin, uniform thickness.

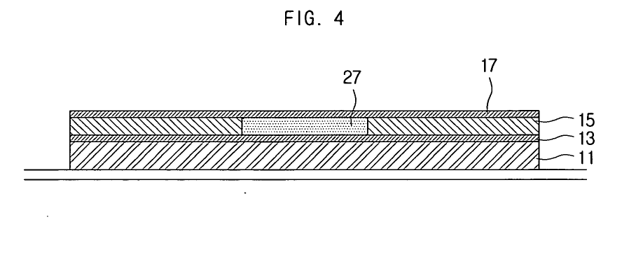

Referring to FIG. 4, a third conductive layer 17 is stacked on the second conductive layer 15. The third conductive layer 17 may be formed by copper plating, etc. The third conductive layer 17 will be made, by subsequent processes, into the upper electrode (18 of FIG. 9) of a capacitor.

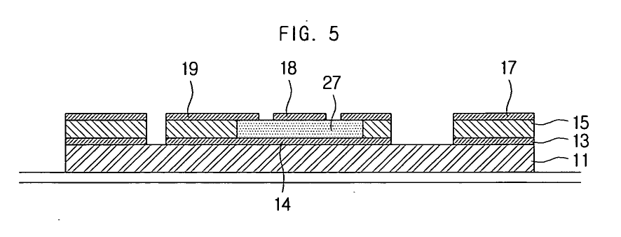

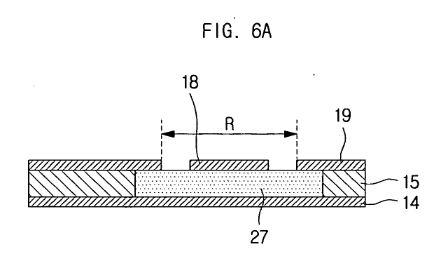

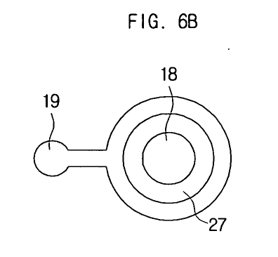

Referring to FIG. 5 and FIGS. 6a to 6b, portions of the first conductive layer 13, second conductive layer 15, and third conductive layer 17 are removed, either simultaneously or separately, to form the upper electrode 18, lower electrode 14, and pad 19 of the capacitor. The upper electrode 18 is located on the upper portion of the dielectric material 27, and is to be electrically connected to an outer layer circuit 25 by a via hole (23 of FIG. 9) that will be formed by subsequent processes. The upper electrode 18 may be formed in the shape of a circle, as is the dielectric material 27, although it is not thus limited. The lower electrode 14 is connected by the second conductive layer 15 to the pad 19, while the pad 19 is connected to the outer layer circuit 25 by a via hole (23 of FIG. 9) that will be formed by subsequent processes. As illustrated in FIGS. 6a and 6b, the pad 19 is insulated from the upper electrode 18, and is positioned in bilateral symmetry with the upper electrode 18 in the middle. Therefore, as illustrated in FIG. 6a, the lower electrode 14 acts as a resistor having a length of R, and since it is possible to form the capacitor and the resistor simultaneously with the method of fabricating a printed circuit board having embedded components according to the present embodiment, the fabrication process can be simplified and the thickness of the board can be reduced.

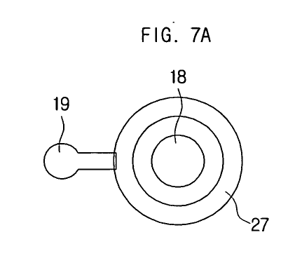

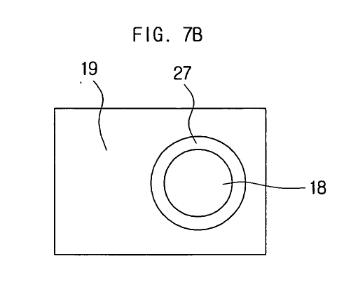

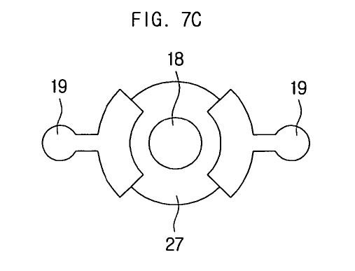

Also, by forming the first conductive layer 13 to have a greater electrical resistance than that of the second conductive layer 15, the resistance properties of the first conductive layer 13 may be altered. When the first conductive layer 13 is a nickel layer, a method of increasing the resistance value of the first conductive layer 13 may include adding phosphor (P) or copper (Cu) to the nickel. Here, as the first conductive layer 13 becomes the lower electrode of the capacitor, the amount of phosphor or copper may be adjusted in consideration of the properties of the capacitor, etc. The pad 19, as illustrated in FIGS. 7ato 7d, may have a variety of shapes.

As illustrated in FIG. 7a, a circular upper electrode 18 may be formed on the dielectric material 27, with a pad 19 formed on one side of the upper electrode 18. Also, as illustrated in FIG. 7b, the pad 19 may be wide, or as illustrated in FIG. 7c, a pair of pads 19 may be formed in bilateral symmetry on both sides of the upper electrode 18.

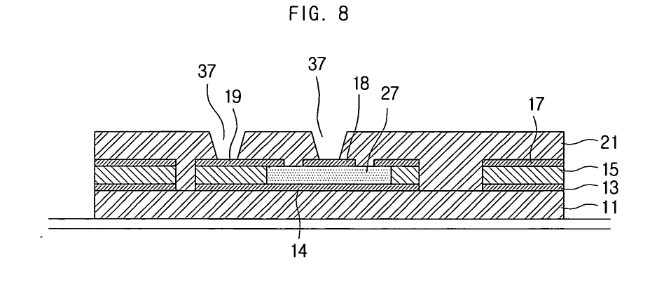

Referring to FIG. 8, an insulation layer 21 is stacked on the third conductive layer 17. The insulation layer 21 is made of an insulation material such as epoxy-type resin, and is filled in the spaces in the first conductive layer 13, second conductive layer 15, and third conductive layer 17 formed as a result of portions being removed by etching, etc. Also, holes 37 are formed in the insulation layer 21 for forming via holes (23 of FIG. 9) that connect the upper electrode 18 and lower electrode 14 with the outer layer circuit 25. The holes 37 are formed in the upper electrode 18 and the pad 19 by means of a drill, etc.

Referring to FIG. 9, an outer layer circuit 25 and via holes 23 are formed on/in the insulation layer 21 by copper plating and etching, etc. The outer layer circuit 25 is connected by the via holes 23 to the upper electrode 18 and the lower electrode 14. Also, an additional layer may be stacked for connecting with the outer layer circuit 25.

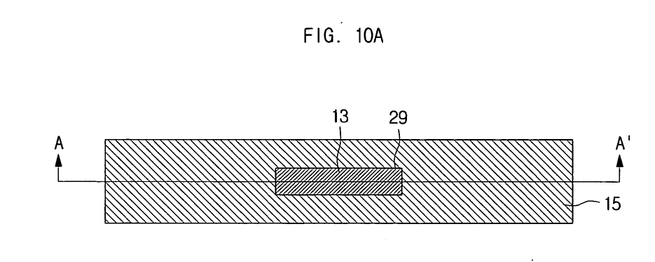

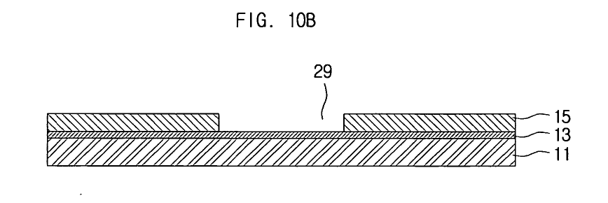

Below, a method of fabricating a printed circuit board having an embedded inductor according to an embodiment of the invention will be described with reference to FIGS. 10a to 1 5b.

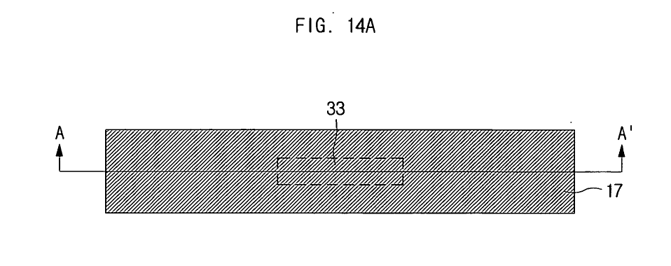

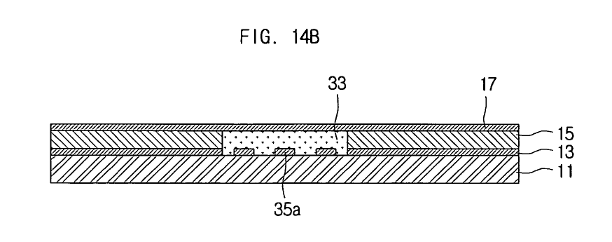

Referring to FIGS. 10a and 10b, a first conductive layer 13 and a second conductive layer 15 are stacked on a substrate 11. A portion of the second conductive layer 15 is removed to form a hole 29 which exposes a portion of the first conductive layer 13 to the exterior. The second conductive layer 15 may be removed by etching, etc. The first conductive layer 13 will be made, by subsequent processes, into the lower inductor parts (35a of FIG. 14b) of the inductor.

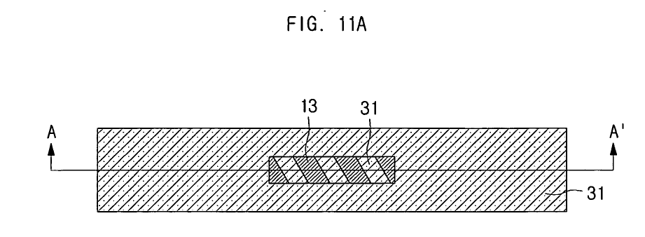

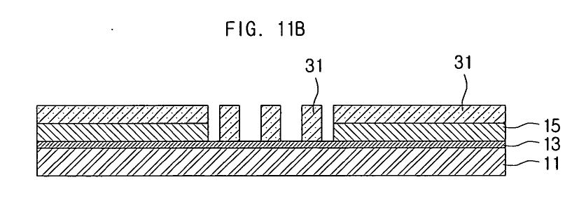

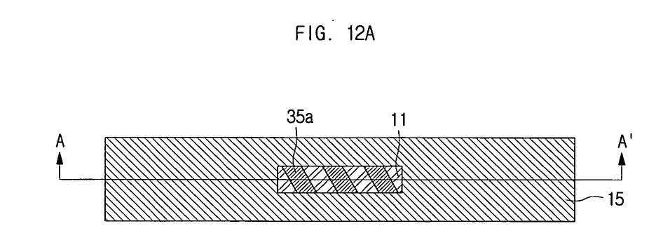

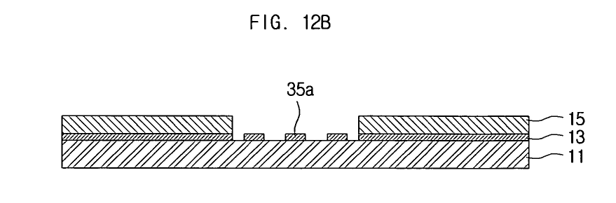

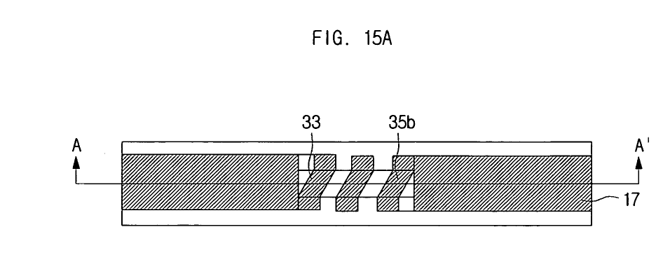

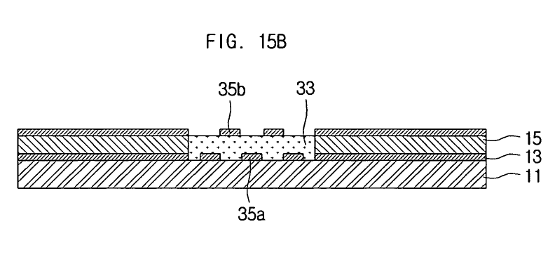

Referring to FIGS. 11 a and 11 b, photosensitive material 31 is coated on portions of the second conductive layer 15 and first conductive layer 13 besides the portions that will be made into the lower inductor parts. Then, the portions not covered by the photosensitive material 31 are removed by an etching process, etc., to form the lower inductor parts 35a, as illustrated in FIG. 12a. As shown in FIGS. 12a and 12b, the lower inductor parts 35a are formed in a plurality with constant intervals, and each will be connected respectively to an upper conductor (35b of FIG. 15b) that will be formed by subsequent processes, to form a coil-shaped inductor.

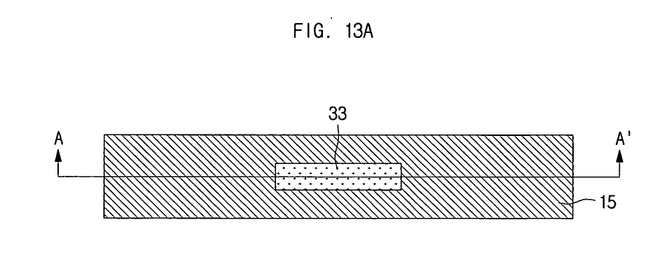

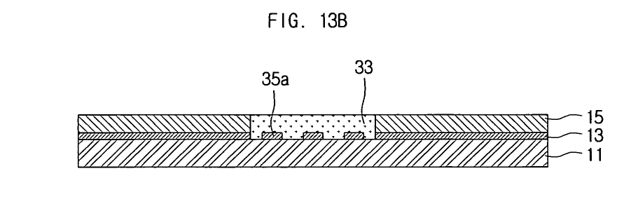

Referring to FIGS. 13a and 13b, insulation material 33 is filled in the hole 29. Methods of such filling may include screenprinting or printing using an inkjet printer, etc. To make the upper surface of the insulation material 33 even with the upper surface of the second conductive layer 15, as illustrated in FIG. 12b, a portion of the insulation material 33 may be polished using an abrasive machine, etc.

A nonconductive, ferromagnetic material may be used for the insulation material 33. Examples of ferromagnetic materials that are nonconductive include ferrite, cobalt, and cobalt alloy sheets. Using a ferromagnetic material for the insulation material 33 improves the efficiency of the inductor. Filling in the ferromagnetic material may be achieved by directly filling ferromagnetic material in the hole 29 or using a ferromagnetic material coated on the surface with an insulation material.

As illustrated in FIGS. 14a and 14b, a third conductive layer 17 is stacked on the second conductive layer 15. The third conductive layer 17 may be stacked by copper plating, etc., and portions thereof will be removed, by subsequent processes, to form upper inductor parts (35b of FIG. 15b).

As illustrated in FIGS. 15a and 15b, portions of the third conductive layer 17 are removed by etching, etc., to form upper inductor parts 35b. The upper inductor parts 35b are electrically connected by the second conductive layer 15 to the lower inductor parts 35a. Thus, the upper inductor parts 35b and lower inductor parts 35a form a coil-shaped inductor.

As described above, the method of fabricating a printed circuit board having an embedded inductor according to embodiments of the invention requires only a process of removing portions of the first conductive layer 13 for forming the lower inductor parts 35a, in addition to the process set forth above of forming a capacitor and resistor, to form an inductor. Thus, the process of fabricating an inductor can be simplified.

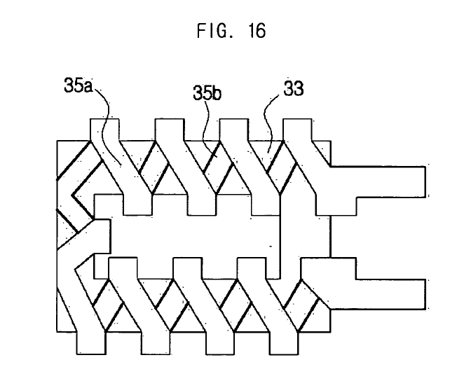

Referring to FIG. 16, the lower inductor parts 35a and upper inductor parts 35b may have the form of a ring. Here, the insulation material 33 is also correspondingly given the form of a ring.

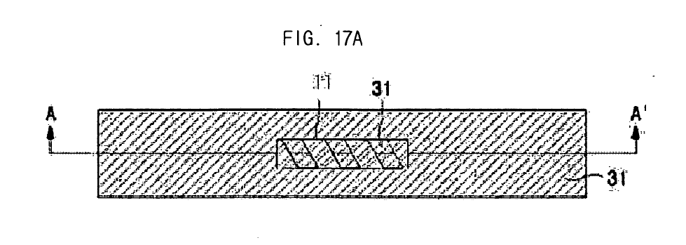

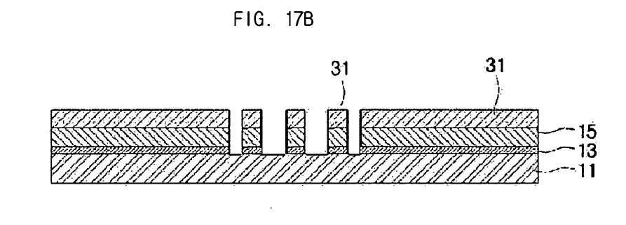

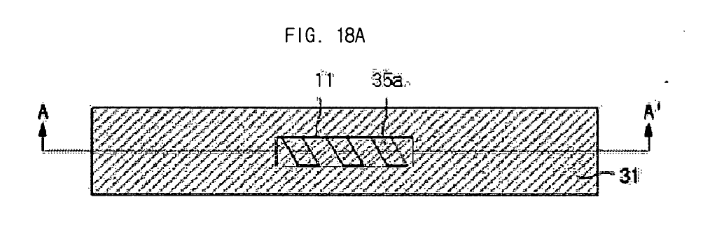

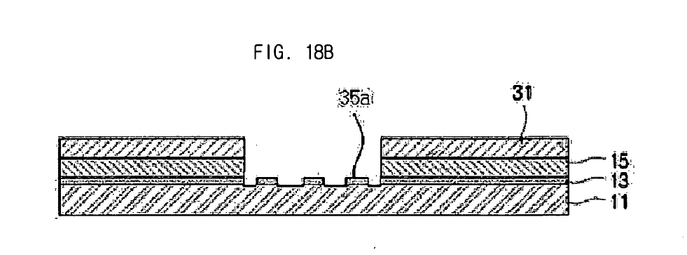

Methods of fabricating an embedded inductor according to other embodiments of the invention will be described with reference to FIGS. 17a to 18b.

As illustrated in FIG. 17a, a method of fabricating an embedded inductor according to another embodiment of the invention includes stacking photosensitive material 31 on the second conductive layer 15 and removing portions of the second conductive layer 15 and first conductive layer 13 simultaneously to form the hole. Then, after removing the photosensitive material 31, portions of the second conductive layer 15 are removed by an etching process, etc., to form the lower inductor parts 35a as in FIG. 18a or 18b. Then, the insulation material 33 is filled in and a third conductive layer 17 is stacked, after which the upper inductor parts 35b are formed to complete the inductor.

The present invention thus provides a method of fabricating a printed circuit board having embedded components, with which it is easy to process the dielectric material to have a uniform thickness.

The invention also provides a method of fabricating a printed circuit board having embedded components, with which the capacitor and the resistor can be implemented simultaneously. The invention also provides a method of fabricating a printed circuit board having embedded components, with which the inductor can be implemented using a process for fabricating the capacitor.

While the present invention has been described with reference to particular embodiments, it is to be appreciated that various changes and modifications may be made by those skilled in the art without departing from the spirit and scope of the present invention, as defined by the appended claims and their equivalents.

1. A method of fabricating a printed circuit board having embedded components, the method comprising:
(a) stacking a first conductive layer and a second conductive layer in order on a substrate;
(b) forming a hole in the second conductive layer and filling with dielectric material;
(c) stacking a third conductive layer on the second conductive layer and removing portions to form an upper electrode located on the dielectric material and a pad electrically connected with the first conductive layer; and
(d) stacking an insulation layer on the third conductive layer and forming a via hole and an outer layer circuit electrically connected with the upper electrode and the pad.

2. The method of claim 1, wherein the substrate is a copper clad laminate.

3. The method of claim 1, wherein the first conductive layer has a greater electrical resistance than that of the second conductive layer.

4. The method of claim 1, wherein the first conductive layer is made of a nickel alloy.

5. The method of claim 1, wherein the second conductive layer is a copper foil.

6. The method of claim 1, wherein the hole is formed by means of a copper etchant.

7. The method of claim 1, wherein the dielectric material is filled by screen printing.

8. The method of claim 1, wherein the dielectric material is filled by means of an inkjet printer.

9. The method of claim 1, wherein a conductive material is plated on the first conductive layer exposed to the exterior after forming the hole.

10. The method of claim 9, wherein the conductive material is made of gold or silver.

11. The method of claim 1, wherein a treatment for forming surface roughness is applied on the first conductive layer exposed to the exterior after forming the hole.

12. The method of claim 1, wherein the third conductive layer is formed by copper plating.

13. The method of claim 1, wherein the first conductive layer is made of a nickel alloy layer stacked on the substrate and a material high in electrical conductivity stacked on the nickel alloy layer.

14. The method of claim 1, wherein a heat-releasing layer is positioned between the substrate and the first conductive layer, the heat-releasing layer having high heat conductivity and is electrically nonconductive.

15. The method of claim 14, wherein the heat-releasing layer is formed by any one of a polymer resin, ceramic, a combination of a polymer resin and ceramic, or metal.

16. A method of fabricating a printed circuit board having embedded components, the method comprising:
(a) stacking a first conductive layer and a second conductive layer in order on a substrate;
(b) forming a hole in the second conductive layer to expose a portion of the first conductive layer to the exterior;
(c) removing the portion of the first conductive layer exposed by the hole to form a portion of a lower inductor part;
(d) filling the hole with insulation material; and
(e) stacking a third conductive layer on the second conductive layer and removing a portion to form a portion of an upper inductor part connected with the lower inductor part.

17. A method of fabricating a printed circuit board having embedded components, the method comprising:
(a) stacking a first conductive layer and a second conductive layer in order on a substrate;
(b) removing portions of the first conductive layer and the second conductive layer and forming a hole to expose a portion of the substrate to the exterior;
(c) removing a portion of the second conductive layer to form a portion of a lower coil of an inductor;
(d) filling the hole with insulation material; and
(e) stacking a third conductive layer on the second conductive layer and removing a portion of the third conductive layer to form a portion of an upper coil connected with the lower coil.

18. The method according to claim 16, wherein the substrate is a copper clad laminate.

19. The method according to claim 17, wherein the substrate is a copper clad laminate.

20. The method according to claim 16, wherein the second conductive layer is a copper foil.

21. The method according to claim 17, wherein the second conductive layer is a copper foil.

22. The method according to claim 16, wherein the hole is formed by means of a copper etchant.

23. The method according to claim 17, wherein the hole is formed by means of a copper etchant.

24. The method of claim 16, wherein the lower inductor part is formed by coating photosensitive material on the first conductive layer and the second conductive layer exposed to the exterior by the hole and removing portions of the first conductive layer by means of an etching process.

25. The method according to claim 16, wherein the insulation material is a nonconductive ferromagnetic material.

26. The method according to of claim 17, wherein the insulation material is a nonconductive ferromagnetic material.

27. The method according to claim 16, wherein the insulation material is a ferromagnetic material treated on a surface thereof with insulation material.

28. The method according to claim 17, wherein the insulation material is a ferromagnetic material treated on a surface thereof with insulation material.
